(19) United States
(12) Patent Application Publication
(10) Pub. No.: US 2026/0206177 A1
(43) Pub. Date: Jul. 16, 2026

(54) EMBEDDED LIQUID COOLING ASSEMBLY AND ELECTRONIC DEVICE

(71) Applicant: AAC Microtech (Changzhou) Co., Ltd., Changzhou City (CN)

(72) Inventors: Xiang Pan, Changzhou (CN); Shasha Xu, Changzhou (CN); Bingyue Bai, Changzhou (CN)

(21) Appl. No.: 19/342,714

(22) Filed: Sep. 29, 2025

Related U.S. Application Data
(63) Continuation of application No. PCT/CN2025/071783, filed on Jan. 10, 2025.

(51) Int. Cl. H05K 7/20; H05K 1/02

(52) U.S. Cl. CPC H05K 7/20254; H05K 1/0203; H05K 7/20272; H05K 7/20436; H05K 2201/10416; H05K 2201/10598

(57) ABSTRACT

An embedded liquid cooling assembly and an electronic device are provided. The embedded liquid cooling assembly includes a circuit board, a power chip and a liquid cooling plate; the liquid cooling plate includes a liquid cooling plate body, and a cooling liquid output tube and a cooling liquid input tube extending from the liquid cooling plate body towards an outside of the circuit board, the liquid cooling plate body is sandwiched between a first circuit board layer and a second circuit board layer, an accommodating cavity is formed in the liquid cooling plate body, and cooling liquid is introduced into the accommodating cavity. The heat dissipation performance of the liquid cooling plate is improved, and the heat dissipation performance of the embedded liquid cooling assembly is better.

### TECHNICAL FIELD

The present disclosure relates to the technical field of heat dissipation, and in particular, to an embedded liquid cooling assembly and an electronic device.

### BACKGROUND

As an important liquid cooling assembly, a liquid cooling plate cools an electronic component by flowing liquid, so as to realize effective temperature control. The liquid cooling plate is usually made of a material with a good heat conduction performance, such as aluminum alloy, and a flow channel is formed in the liquid cooling plate for circulating of cooling liquid. The electronic component (such as a battery module) is mounted at a surface of the water cooling plate, and heat is transferred to the cooling liquid through a heat conducting medium, and then taken away by the cooling liquid and discharged out of a system.

However, for an existing liquid cooling plate, when the liquid cooling plate dissipates heat of a power chip, due to the problems of encapsulation and structural designing, the heat dissipation efficiency thereof is low, and meanwhile, leakage, performance degradation and other problems may occur in long-term use, thereby affecting the reliability and stability of the power chip.

Therefore, it needs to provide a new embedded liquid cooling assembly to solve the above technical problems.

### SUMMARY

The present disclosure aims to provide an embedded liquid cooling assembly and an electronic device, which are intended to solve the problems that an existing liquid cooling plate has a poor heat dissipation effect on a power chip.

In order to achieve the above objective, in a first aspect, the present disclosure provides embedded liquid cooling assembly, including a circuit board, a power chip and a liquid cooling plate, the circuit board is a multilayer circuit board, and the circuit board includes a first circuit board layer for attaching the power chip, a second circuit board layer for serving as a bottom plate, and a third circuit board layer sandwiched between the first circuit board layer and the second circuit board layer; the liquid cooling plate is sandwiched between the first circuit board layer and the second circuit board layer and arranged at the same layer as the third circuit board layer, and an orthographic projection of the liquid cooling plate towards the first circuit board layer covers the power chip; the liquid cooling plate includes a liquid cooling plate body, and a cooling liquid output tube and a cooling liquid input tube extending from the liquid cooling plate body towards an outside of the circuit board, the liquid cooling plate body is sandwiched between the first circuit board layer and the second circuit board layer, an accommodating cavity is formed in the liquid cooling plate body, cooling liquid is introduced into the accommodating cavity, and the cooling liquid output tube and the cooling liquid input tube are respectively communicated with the accommodating cavity.

In an improvement, the accommodating cavity is provided with a plurality of heat dissipation members arranged at intervals.

In an improvement, the plurality of heat dissipation members are heat dissipation plates, every two adjacent heat dissipation plates are spaced apart to form a microchannel, and all the heat dissipation plates divide the accommodating cavity into a plurality of microchannels which are communicated with each other.

In an improvement, the plurality of heat dissipation members are finned tubes, and the finned tubes are arranged in an array.

In an improvement, the cooling liquid output tube and the cooling liquid input tube extend from the liquid cooling plate body in a direction perpendicular to the circuit board or in a direction parallel to the circuit board.

In an improvement, the first circuit board layer is provided with at least one through-hole, a side of the liquid cooling plate body close to the first circuit board layer is provided with at least one convex structure, and the at least one convex structure passes through the at least one through-hole to cause the liquid cooling plate body to be attached to and contact the power chip.

In an improvement, the third circuit board layer is of a double-layer structure; the liquid cooling plate body is embedded into the third circuit board layer and attached to and contacts the first circuit board layer and the second circuit board layer.

In an improvement, the liquid cooling plate is made of one of copper, aluminum, stainless steel or titanium alloy.

In an improvement, the liquid cooling plate is connected to a grounding end on the first circuit board layer or the second circuit board layer.

In a second aspect, the present disclosure further provides an electronic device, including the embedded liquid cooling assembly according to the above embodiments.

### BRIEF DESCRIPTION OF DRAWINGS

To better describe the technical solutions in embodiments of the present disclosure, the following briefly describes the accompanying drawings required for the description of the embodiments. Apparently, the accompanying drawings in the following description show merely some embodiments of the present disclosure, and a person of ordinary skill in the art may still derive other drawings from these accompanying drawings without creative efforts.

FIG. 1 is a schematic perspective structural diagram of an embedded liquid cooling assembly according to an embodiment of the present disclosure;

FIG. 2 is a schematic perspective exploded structural diagram of an embedded liquid cooling assembly according to the embodiment of the present disclosure;

FIG. 3 is a sectional view taken along A-A shown in FIG. 1;

FIG. 4 is a sectional view when a heat dissipation member of an embedded liquid cooling assembly according to an embodiment of the present disclosure is a heat dissipation plate; and

FIG. 5 is a sectional view when a heat dissipation member of an embedded liquid cooling assembly according to an embodiment of the present disclosure is a finned tube.

In the drawings, 100: embedded liquid cooling assembly; 1: circuit board; 11: first circuit board layer; 111: through-hole; 12: second circuit board layer; 13: third circuit board layer; 2: power chip; 3: liquid cooling plate; 31: liquid cooling plate body; 311: accommodating cavity; 312: heat dissipation member; 32: cooling liquid input tube; 33: cooling liquid output tube; 34: convex structure.

### DESCRIPTION OF EMBODIMENTS

The technical solutions in the embodiments of the present disclosure are described with reference to the accompanying drawings in the embodiments of the present disclosure, and apparently, the described embodiments are not all but only a part of the embodiments of the present disclosure. All other embodiments obtained by a person of ordinary skill in the art based on the embodiments of the present disclosure without creative efforts shall fall within the protection scope of the present disclosure.

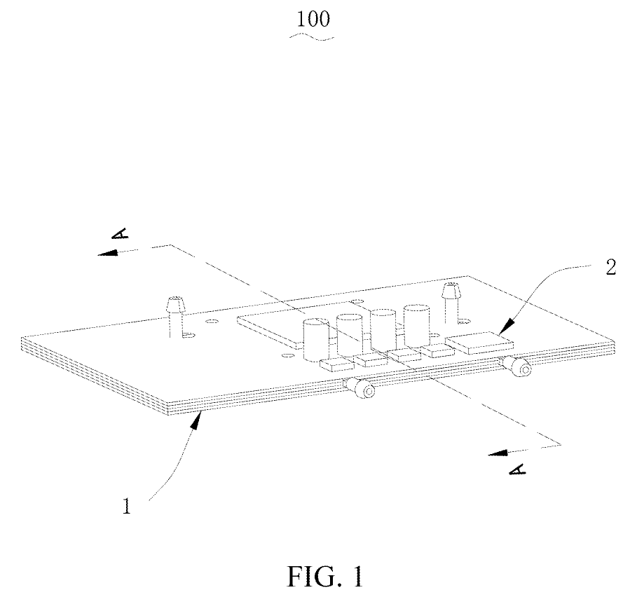

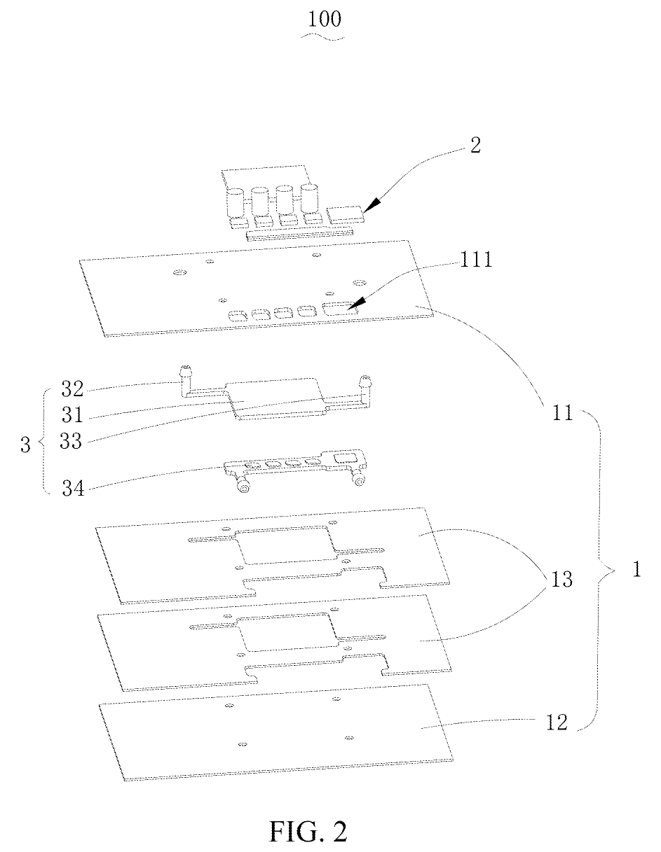

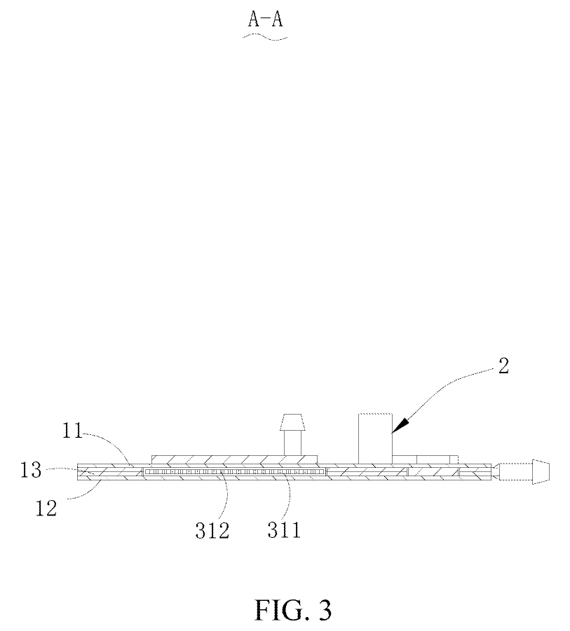

With reference to FIG. 1 to FIG. 3, an embodiment of the present disclosure provides an embedded liquid cooling assembly 100, including a circuit board 1, a power chip 2 and a liquid cooling plate 3. The circuit board 1 is a multilayer circuit board, and the circuit board 1 includes a first circuit board layer 11 for attaching the power chip 2, a second circuit board layer 12 for serving as a bottom plate, and a third circuit board layer 13 sandwiched between the first circuit board layer 11 and the second circuit board layer 12.

The liquid cooling plate 3 is sandwiched between the first circuit board layer 11 and the second circuit board layer 12 and arranged at the same layer as the third circuit board layer 13, and an orthographic projection of the liquid cooling plate 3 towards the first circuit board layer 11 covers the power chip 2.

The liquid cooling plate 3 includes a liquid cooling plate body 31, and a cooling liquid output tube 33 and a cooling liquid input tube 32 extending from the liquid cooling plate body 31 towards the outside of the circuit board 1. The liquid cooling plate body 31 is sandwiched between the first circuit board layer 11 and the second circuit board layer 12, an accommodating cavity 311 is formed in the liquid cooling plate body 31, cooling liquid is introduced into the accommodating cavity 311, and the cooling liquid output tube 33 and the cooling liquid input tube 32 are respectively communicated with the accommodating cavity 311.

In an example, the cooling liquid flows into the accommodating cavity 311 through the cooling liquid input tube 32 and flows out through the cooling liquid output tube 33, so that the temperatures of the circuit board 1 and the power chip 2 can be adjusted through the liquid cooling plate 3, and the stability of the circuit board 1 and the power chip 2 is improved.

In this embodiment, the accommodating cavity 311 is provided with a plurality of heat dissipation members 312 arranged at intervals, and the heat exchange area between the liquid cooling plate 3 and a cooling medium (i.e., cooling liquid) is effectively increased by the heat dissipation members 312, thus effectively improving the heat dissipation efficiency of the liquid cooling plate 3.

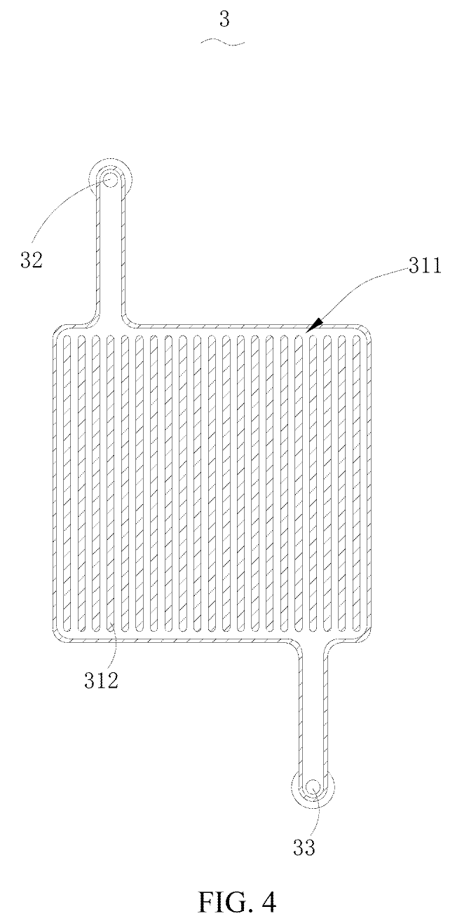

In an embodiment, the heat dissipation members 312 are heat dissipation plates, every two adjacent heat dissipation plates are spaced apart to form a microchannel, and all the heat dissipation plates divide the accommodating cavity 311 into a plurality of microchannels which are communicated with each other. With reference to FIG. 4, which is a sectional view when a heat dissipation member 312 of an embedded liquid cooling assembly 100 according to an embodiment of the present disclosure is a heat dissipation plate. By configuring the heat dissipation members 312 in heat dissipation plate shapes and vertically arranging the heat dissipation members in the accommodating cavity 311, the heat exchange area between the liquid cooling plate 3 and the cooling medium is effectively increased, and the heat dissipation efficiency is improved.

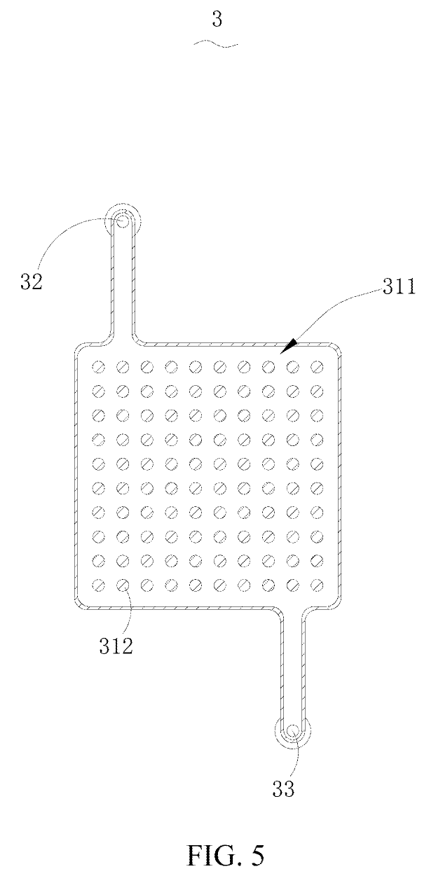

In an embodiment, the heat dissipation members 312 are finned tubes, and the finned tubes are arranged in an array. With reference to FIG. 5, which is a sectional view when a heat dissipation member 312 of an embedded liquid cooling assembly 100 according to an embodiment of the present disclosure is a finned tube. By configuring the heat dissipation members 312 in finned tube shapes and vertically arranging the heat dissipation members in the accommodating cavity 311, the heat exchange area between the liquid cooling plate 3 and the cooling medium is effectively increased, and the heat dissipation efficiency is improved.

In an embodiment, the cooling liquid output tube 33 and the cooling liquid input tube 32 extend from the liquid cooling plate body 31 in a direction perpendicular to the circuit board 1 or in a direction parallel to the circuit board 1.

Exemplarily, in an embodiment, the cooling liquid output tube 33 and the cooling liquid input tube 32 extend from the liquid cooling plate body 31 in the direction perpendicular to the circuit board 1, and the cooling liquid output tube 33 and the cooling liquid input tube 32 are respectively arranged at two opposite ends of the liquid cooling plate body 31.

In an embodiment, the cooling liquid output tube 33 and the cooling liquid input tube 32 extend from the liquid cooling plate body 31 in the direction parallel to the circuit board 1, and the cooling liquid output tube 33 and the cooling liquid input tube 32 are respectively arranged at two opposite ends of the liquid cooling plate body 31.

In an embodiment, two liquid cooling plates 3 are provided, the cooling liquid output tube 33 and the cooling liquid input tube 32 of one liquid cooling plate 3 extend from the liquid cooling plate body 31 in the direction perpendicular to the circuit board 1, and the cooling liquid output tube 33 and the cooling liquid input tube 32 of the other liquid cooling plate 3 extend from the liquid cooling plate body 31 in the direction parallel to the circuit board 1.

In an embodiment, the first circuit board layer 11 is provided with at least one through-hole 111, a side of the liquid cooling plate 3 close to the first circuit board layer 11 is provided with at least one convex structure 34, and the convex structure 34 passes through the through-hole 111 to cause the liquid cooling plate 3 to be attached to and contact the power chip 2. Since the liquid cooling plate 3 is directly attached to and contacts the power chip 2, the efficiency of heat dissipation of the power chip 2 by the liquid cooling plate 3 is effectively improved while no additional space is added.

In an embodiment, the third circuit board layer 13 is of a double-layer structure; the liquid cooling plate body 31 is embedded into the third circuit board layer 13 and attached to and contacts the first circuit board layer 11 and the second circuit board layer 12. In an example, the liquid cooling plate body 31 is encapsulated in the circuit board 1 by an embedded component encapsulation technology, so that the liquid cooling plate 3 has a better heat dissipation effect on the circuit board 1.

In an embodiment, the liquid cooling plate 3 is made of one of copper, aluminum, stainless steel and titanium alloy. In an example, the liquid cooling plate 3 is made of high heat conduction metal, and the present disclosure is not limited to the above materials.

In an embodiment, the liquid cooling plate 3 is connected to a grounding end on the first circuit board layer 11 or the second circuit board layer 12. Therefore, the circuit stability of the embedded liquid cooling assembly 100 is improved.

Compared with the prior art, the embedded liquid cooling assembly according to the present disclosure includes the circuit board, the power chip and the liquid cooling plate; the circuit board is the multilayer circuit board, and the circuit board includes the first circuit board layer for attaching the power chip, the second circuit board layer for serving as the bottom plate, and the third circuit board layer sandwiched between the first circuit board layer and the second circuit board layer; the liquid cooling plate is sandwiched between the first circuit board layer and the second circuit board layer and arranged at the same layer as the third circuit board layer, and the orthographic projection of the liquid cooling plate towards the first circuit board layer covers the power chip; the liquid cooling plate includes the liquid cooling plate body, and the cooling liquid output tube and the cooling liquid input tube extending from the liquid cooling plate body towards the outside of the circuit board, the liquid cooling plate body is sandwiched between the first circuit board layer and the second circuit board layer, the accommodating cavity is formed in the liquid cooling plate body, and the cooling liquid is introduced into the accommodating cavity. In the present disclosure, the liquid cooling plate is arranged between the first circuit board layer and the second circuit board layer, thus increasing the contact area of the liquid cooling plate and the circuit board. The liquid cooling plate directly contacts the power chip, thus effectively improving the heat dissipation effect on the circuit board and the power chip. Meanwhile, the heat dissipation member is arranged in the accommodating cavity in the liquid cooling plate body, thereby increasing the heat exchange area of the liquid cooling plate and the cooling liquid, and improving the heat dissipation performance of the liquid cooling plate, so that the heat dissipation performance of the embedded liquid cooling assembly according to the present disclosure is better.

An embodiment of the present disclosure further provides an electronic device, including the embedded liquid cooling assembly 100 according to the above embodiments. It can be understood that the electronic device designed based on the embedded liquid cooling assembly 100 according to the embodiments of the present disclosure can achieve a good heat dissipation performance based on the structural design of the embedded liquid cooling assembly 100, reference may be made to the description of the above embodiments, and details are not repeated herein.

The above description only illustrates some embodiments of the present disclosure, and it should be noted that improvements can be made by those of ordinary skill in the art without departing from the concept of the present disclosure, and all fall within the protection scope of the present disclosure.

What is claimed is:

1. An embedded liquid cooling assembly, comprising a circuit board, a power chip and a liquid cooling plate, wherein the circuit board is a multilayer circuit board, and the circuit board comprises a first circuit board layer for attaching the power chip, a second circuit board layer for serving as a bottom plate, and a third circuit board layer sandwiched between the first circuit board layer and the second circuit board layer;
the liquid cooling plate is sandwiched between the first circuit board layer and the second circuit board layer and arranged at the same layer as the third circuit board layer, and an orthographic projection of the liquid cooling plate towards the first circuit board layer covers the power chip;
the liquid cooling plate comprises a liquid cooling plate body, and a cooling liquid output tube and a cooling liquid input tube extending from the liquid cooling plate body towards an outside of the circuit board, the liquid cooling plate body is sandwiched between the first circuit board layer and the second circuit board layer, an accommodating cavity is formed in the liquid cooling plate body, cooling liquid is introduced into the accommodating cavity, and the cooling liquid output tube and the cooling liquid input tube are respectively communicated with the accommodating cavity.

2. The embedded liquid cooling assembly as described in claim 1, wherein the accommodating cavity is provided with a plurality of heat dissipation members arranged at intervals.

3. The embedded liquid cooling assembly as described in claim 2, wherein the plurality of heat dissipation members are heat dissipation plates, every two adjacent heat dissipation plates are spaced apart to form a microchannel, and all the heat dissipation plates divide the accommodating cavity into a plurality of microchannels which are communicated with each other.

4. The embedded liquid cooling assembly as described in claim 2, wherein the plurality of heat dissipation members are finned tubes, and the finned tubes are arranged in an array.

5. The embedded liquid cooling assembly as described in claim 1, wherein the cooling liquid output tube and the cooling liquid input tube extend from the liquid cooling plate body in a direction perpendicular to the circuit board or in a direction parallel to the circuit board.

6. The embedded liquid cooling assembly as described in claim 1, wherein the first circuit board layer is provided with at least one through-hole, a side of the liquid cooling plate body close to the first circuit board layer is provided with at least one convex structure, and the at least one convex structure passes through the at least one through-hole to cause the liquid cooling plate body to be attached to and contact the power chip.

7. The embedded liquid cooling assembly as described in claim 1, wherein the third circuit board layer is of a double-layer structure; the liquid cooling plate body is embedded into the third circuit board layer and attached to and contacts the first circuit board layer and the second circuit board layer.

8. The embedded liquid cooling assembly as described in claim 1, wherein the liquid cooling plate is made of one of copper, aluminum, stainless steel or titanium alloy.

9. The embedded liquid cooling assembly as described in claim 1, wherein the liquid cooling plate is connected to a grounding end on the first circuit board layer or the second circuit board layer.

10. An electronic device, comprising an embedded liquid cooling assembly comprising a circuit board, a power chip and a liquid cooling plate, wherein the circuit board is a multilayer circuit board, and the circuit board comprises a first circuit board layer for attaching the power chip, a second circuit board layer for serving as a bottom plate, and a third circuit board layer sandwiched between the first circuit board layer and the second circuit board layer;
the liquid cooling plate is sandwiched between the first circuit board layer and the second circuit board layer and arranged at the same layer as the third circuit board layer, and an orthographic projection of the liquid cooling plate towards the first circuit board layer covers the power chip;
the liquid cooling plate comprises a liquid cooling plate body, and a cooling liquid output tube and a cooling liquid input tube extending from the liquid cooling plate body towards an outside of the circuit board, the liquid cooling plate body is sandwiched between the first circuit board layer and the second circuit board layer, an accommodating cavity is formed in the liquid cooling plate body, cooling liquid is introduced into the accommodating cavity, and the cooling liquid output tube and the cooling liquid input tube are respectively communicated with the accommodating cavity.
